(19) United States
(12) Patent Application Publication
(10) Pub. No.: US 2014/0037889 A1
(43) Pub. Date: Feb. 6, 2014

(54) INSULATOR FOR BUILD-UP PCB AND METHOD OF MANUFACTURING PCB USING THE SAME

(71) Applicant: SAMSUNG ELECTRO-MECHANICS CO., LTD., Suwon-si (KR)

(72) Inventors: Jong-Yoon JANG, Suwon-si (KR); Jae-Choon CHO, Suwon-si (KR); Dong-Joo SHIN, Suwon-si (KR); Hee-Sun CHUN, Suwon-si (KR); Sung-Hyun KIM, Suwon-si (KR); Choon-Keun LEE, Suwon-si (KR)

(73) Assignee: SAMSUNG ELECTRO-MECHANICS CO., LTD., Suwon-si (KR)

(21) Appl. No.: 13/960,532

(22) Filed: Aug. 6, 2013

(30) Foreign Application Priority Data
Aug. 6, 2012 (KR) 10-2012-0085796

(51) Int. Cl. H05K 1/02; H05K 3/00

(52) U.S. Cl. CPC H05K 1/02; H05K 3/00
USPC 428/78; 428/189; 156/154

(57) ABSTRACT

Disclosed are an insulator for a build-up PCB and a method of manufacturing a printed circuit board using the insulator. The insulator for a build-up PCB in accordance with an embodiment of the present invention includes: an insulation film layer, of which one surface has an area corresponding to a circuit board to be built-up; and a cover film layer, which is stacked on the insulation film layer and of which one surface has a larger area than the one surface of the insulation film layer so as to cover an entire outer perimeter of the insulation film layer.

### CROSS-REFERENCE TO RELATED APPLICATIONS

This application claims the benefit of Korean Patent Application No. 10-2012-0085796, filed with the Korean Intellectual Property Office on Aug. 6, 2012, the disclosure of which is incorporated herein by reference in its entirety.

### BACKGROUND

1. Technical Field

The present invention relates to an insulator for a build-up printed circuit board and a method of manufacturing a printed circuit board using the insulator.

2 Background Art

In a known method of manufacturing a multi-layer printed wiring board, multiple sheets of prepreg, which is epoxy resin impregnated in glass fabric and B-staged, are interposed and stack-pressed as insulation adhesive layers in an inner-layer circuit board, in which circuit is formed, and inter-layer conduction is made by a through-hole. However, this method requires a large-scale facility and a long operation time to perform heating and compression molding through stack-pressing, thereby increasing the production cost. Moreover, due to the use of the relatively dielectric glass fabric in the prepreg sheets, there are limits to minimizing the inter-layer thickness, and the dielectric characteristics become unstable due to CAF.

As a method for solving these problems, the multi-layer printed wiring board is fabricated with a build-up method, in which organic insulation layers are alternately stacked over the conductor layer of the inner-layer circuit board.

In the case where these adhesive films are vacuum-stacked under a heated and pressurized condition, the thermal flexibility of the adhesive makes the adhesive leak in at the end portion of the adhesive films, resulting in contamination of the press surface or laminate roll.

The background art of the present invention is disclosed in Korean Patent Publication Number 2000-0047687 (Publication Date: Jul. 25, 2000: METHOD OF VACUUM-LAMINATING ADHESIVE FILM).

### SUMMARY

The present invention provides an insulator for a build-up printed circuit board and a method of manufacturing a printed circuit board using the insulator that can prevent the printed circuit board from being contaminated by a foreign substance by forming a cover film layer, which covers an insulation film layer, to be larger than the insulation film layer.

An aspect of the present invention features an insulator for a build-up printed circuit board. The insulator for a build-up printed circuit board in accordance with an embodiment of the present invention includes: an insulation film layer, of which one surface has an area corresponding to a circuit board to be built-up; and a cover film layer, which is stacked on the insulation film layer and of which one surface has a larger area than the one surface of the insulation film layer so as to cover an entire outer perimeter of the insulation film layer.

The insulation film layer can be provided in plurality, and the plurality of insulation film layers can be separated and arranged linearly on the cover film layer.

The insulation film layer can be stacked on the cover film layer by a screen-printing method.

Another aspect of the present invention features a method of manufacturing a build-up printed circuit board. The method of manufacturing a build-up printed circuit board in accordance with an embodiment of the present invention includes: providing an insulator for a build-up printed circuit board, the insulator comprising an insulation film layer, of which one surface has an area corresponding to a circuit board to be built-up, and a cover film layer, which is stacked on the insulation film layer and of which one surface has a larger area than the one surface of the insulation film layer so as to cover an entire outer perimeter of the insulation film layer; stacking the insulator for a build-up printed circuit board on the circuit board in such a way that the insulation film layer faces the circuit board; pressing the insulator for a build-up printed circuit board so that the insulation film layer is adhered to the circuit board; and exfoliating and removing the cover film layer.

### BRIEF DESCRIPTION OF THE DRAWINGS

FIG. 1 is a perspective view showing an insulator for a build-up PCB in accordance with an embodiment of the present invention.

FIG. 2 is a perspective view showing pressing the insulator for a build-up PCB in accordance with an embodiment of the present invention.

FIG. 3 is a perspective view showing exfoliating and removing a cover film layer in accordance with an embodiment of the present invention.

### DETAILED DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the ideas and scope of the present invention. Throughout the description of the present invention, when describing a certain relevant conventional technology is determined to evade the point of the present invention, the pertinent detailed description will be omitted.

Terms such as “first” and “second” can be used in describing various elements, but the above elements shall not be restricted to the above terms. The above terms are used only to distinguish one element from the other.

The terms used in the description are intended to describe certain embodiments only, and shall by no means restrict the present invention. Unless clearly used otherwise, expressions in a singular form include a meaning of a plural form. In the present description, an expression such as “comprising” or “including” is intended to designate a characteristic, a number, a step, an operation, an element, a part or combinations thereof, and shall not be construed to preclude any presence or possibility of one or more other characteristics, numbers, steps, operations, elements, parts or combinations thereof.

When one element is said to be “coupled” with another element, it includes not only a case where the one element makes a physical contact with the other element but also a case where there is another element interposed between the one element and the other element and where a physical contact is made between these elements.

Hereinafter, an insulator for a build-up PCB and a method of manufacturing a PCB using the insulator in accordance with certain embodiments will be described in detail with reference to the accompanying drawings. Identical or corresponding elements will be given the same reference numerals, regardless of the figure number, and any redundant description of the identical or corresponding elements will not be repeated.

The insulator for a build-up PCB in accordance with an embodiment of the present invention is stacked over a circuit board 100 and includes an insulation film layer 200 and a cover film layer 300.

One surface of the insulation film layer 200 is formed to have an area corresponding to the circuit board 100 that is to be built-up, and the insulation film layer 200 is stacked over the circuit board 100.

The cover film layer 300 is stacked on the insulation film layer 200 in order to protect the insulation film layer 200 from a press 400 when the insulation film layer 200 is pressed by the press 400 for adhesion to the circuit board 100.

Accordingly, it is required that one surface of the cover film layer 300 is larger than the one surface of the insulation film layer 200 so as to cover all of an upper portion and an outer perimeter of the upper portion of the insulation film layer 200.

In a typical structure of a build-up film, a plastic film is adhered to an upper portion of a build-up insulation film, and a margin layer is formed in the shape of the plastic film on one surface of the plastic film for exfoliation of the plastic film after pressing.

However, since the margin layer is formed on one surface of the circuit board 100 only, resin may be flowed out of the plastic film and possibly become a foreign substance, if the insulation film is adhered to a surface of the circuit board by heat and pressure.

Therefore, the cover film layer 300 of the insulator for a build-up PCB in accordance with an embodiment of the present invention is formed to have a larger area than the area of the insulation film layer 200 so as to cover the entire outer perimeter of the insulation film layer 200.

By having the cover film layer 300 cover the entire outer perimeter of the insulation film layer 200, the resin is not flowed out when pressed by the press 400, preventing the circuit board 100 from being contaminated by foreign substances.

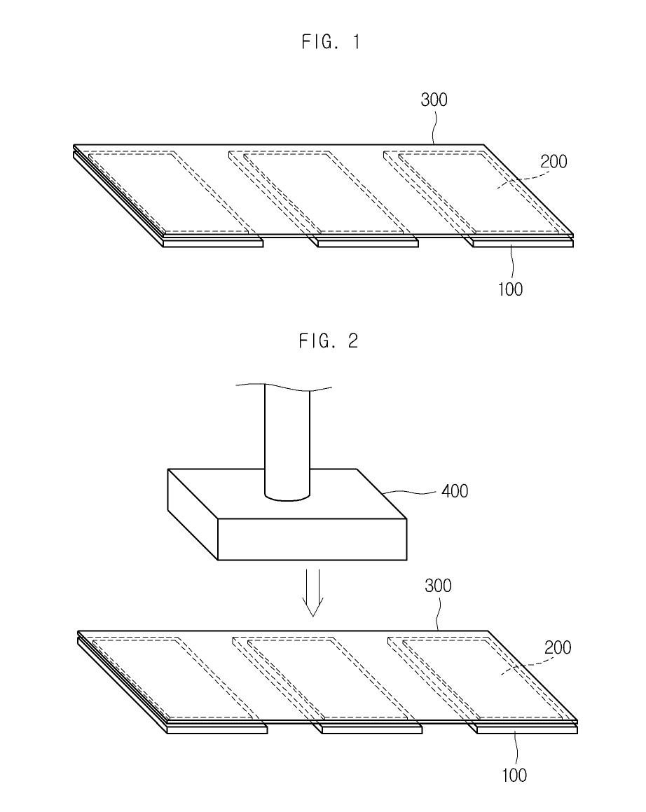

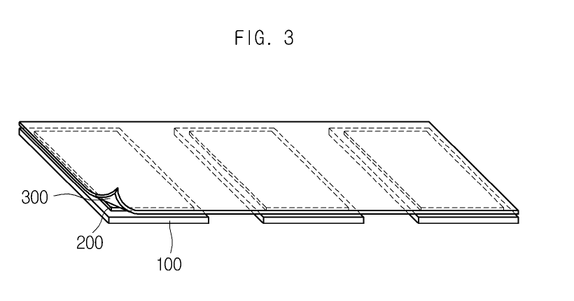

As illustrated in FIG. 1 to FIG. 3, the insulation film layer 200 can be severed into a plurality of insulation films according to the size of a board to which the insulation film layer 200 is to be applied.

In such a case, each of the insulation film layers 200 can have margins formed on all 4 external sides, and the formed margins can prevent the resin from flowing out even when pressed by the press 400.

The plurality of insulation film layers 200 can be linearly separated and arranged on the cover film layer 300 according to the size and number of the boards.

Here, the insulation film layer 200 and the cover film layer 300 can be attached to each other by a screen-printing method. Moreover, the insulation film layer 200 and the cover film layer 300 can be attached to each other by attaching a liner to the cover film layer 300 in a casting process and removing the liner immediately after the casting process.

A board can be fabricated by using the above-described insulator for a build-up PCB.

A method of manufacturing a circuit board in accordance with another embodiment of the present invention can include: providing an insulator for a build-up PCB; stacking the insulator for a build-up board on a circuit board 100; pressing the insulator for a build-up board; and exfoliating and removing a cover film layer 300.

In the step of providing an insulator for a build-up PCB, the insulator for a build-up PCB includes an insulation film layer 200, of which one surface has an area corresponding to the circuit board 100 to be built-up, and the cover film layer 300, which is stacked over the insulation film layer 200 and of which one surface is formed to have a larger area than the area of the one surface of the insulation film layer 200 so as to cover an entire outer perimeter of the insulation film layer 200.

After providing the insulator for a build-up PCB, the insulator for a build-up PCB can be stacked on the circuit board 100 in such a way that the insulation film layer 200 of the insulator for a build-up PCB faces one surface of the PCB to which the insulator for a build-up PCB is to be applied.

Afterwards, the insulator for a build-up PCB can be pressed by a press 400 so that the insulation film layer 200 is adhered to the circuit board 100.

After the pressing, the PCB can be fabricated by exfoliating and removing the cover film layer 300.

By forming the cover film layer 300 of the insulator for a build-up PCB to be larger than the insulation film layer 200 when fabricating the PCB, it becomes possible to prevent resin from flowing out when being pressed.

Although certain embodiments of the present invention have been described, it shall be appreciated that a very large number of modifications and permutations of the present invention are possible by anyone ordinarily skilled in the art to which the present invention pertains by supplementing, modifying, deleting and/or adding certain elements without departing from the technical ideas of the present invention, of which the scope shall be defined by the claims appended below.

What is claimed is:

1. An insulator for a build-up printed circuit board, comprising:
an insulation film layer, of which one surface has an area corresponding to a circuit board to be built-up; and
a cover film layer, which is stacked on the insulation film layer and of which one surface has a larger area than the one surface of the insulation film layer so as to cover an entire outer perimeter of the insulation film layer.

2. The insulator of claim 1, wherein the insulation film layer is provided in plurality, and
wherein the plurality of insulation film layers are separated and arranged linearly on the cover film layer.

3. The insulator of claim 1, wherein the insulation film layer is stacked on the cover film layer by a screen-printing method.

4. A method of manufacturing a build-up printed circuit board, comprising:
providing an insulator for a build-up printed circuit board, the insulator comprising an insulation film layer, of which one surface has an area corresponding to a circuit board to be built-up, and a cover film layer, which is stacked on the insulation film layer and of which one surface has a larger area than the one surface of the insulation film layer so as to cover an entire outer perimeter of the insulation film layer;
stacking the insulator for a build-up printed circuit board on the circuit board in such a way that the insulation film layer faces the circuit board;
pressing the insulator for a build-up printed circuit board so that the insulation film layer is adhered to the circuit board; and
exfoliating and removing the cover film layer.
